(19) United States
(12) Patent Application Publication
(10) Pub. No.: US 2026/0056476 A1
(43) Pub. Date: Feb. 26, 2026

(54) METHOD FOR EVALUATING MEASUREMENT VALUES OF AN ABERRATION OF A PROJECTION LENS

(71) Applicants: Carl Zeiss SMT GmbH, Oberkochen (DE); ASML NETHERLANDS B.V., Veldhoven (NL)

(72) Inventors: Timur TUDOROVSKIY, Beuningen (NL); Vinh Huu HO, Veldhoven (NL); Eva SCHNEIDER, Aalen (DE); Maike OP HET VELD, Valkenswaard (NL); Robert HARMES, Aalen (DE); Erwin Diederik STINSTRA, Eindhoven (NL)

(21) Appl. No.: 19/375,787

(22) Filed: Oct. 31, 2025

Related U.S. Application Data
(63) Continuation of application No. PCT/EP2024/061570, filed on Apr. 26, 2024.

(30) Foreign Application Priority Data
May 3, 2023 (DE) 10 2023 111 478.6

(51) Int. Cl. G03F 7/00; G01M 11/02

(52) U.S. Cl. CPC G03F 7/706; G01M 11/025; G03F 7/70225; G03F 7/70266

(57) ABSTRACT

A method for evaluating measured values of projection lens (22) aberration(s) determined at plural field points in a field plane of the projection lens which has a plurality of optical elements (E1-E4) guiding exposure radiation and an optical element manipulator system (M1-M4) for carrying out a rigid body movement. The method includes: providing a fit function (62) having a polynomial function (64) that depends on the spatial coordinates defining a field plane and a rigid-body-sensitivities (70) term (66) for multiple locations in the field plane each describing a dependence of the aberration (63) on a degree of freedom of movement (68) at the relevant locations that is controllable by the manipulator system. The method further includes extrapolating the measured values (50) determined at the plural field points (52) to further field points (56) of the projection lens by fitting the fit function to the determined measured values.

### CROSS REFERENCE TO RELATED APPLICATIONS

This is a Continuation of International Application PCT/EP2024/061570 which has an international filing date of Apr. 26, 2024, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2023 111 478.6 filed on May 3, 2023.

### FIELD

The invention relates to a method for evaluating measured values of at least one aberration of a projection lens of a microlithographic projection exposure apparatus, a method for operating such a projection exposure apparatus and a microlithographic projection exposure apparatus.

### BACKGROUND

A projection lens with wavefront aberrations that are as small as possible is required to guarantee imaging of mask structures onto a substrate as precisely as possible. Therefore, projection lenses are equipped with manipulators, which allow the correction of wavefront errors by changing the state of individual optical elements of the projection lens. Examples of such a change in state include: a change of pose in one or more of the six rigid-body degrees of freedom of the relevant optical element, application of heat and/or cold to the optical element, and a deformation of the optical element. To this end, the aberration characteristic of the projection lens is usually measured regularly and, if appropriate, changes in the aberration characteristic between the individual measurements are determined by simulation. In this regard, for example, lens element heating effects can be taken into account computationally. The manipulator changes to be implemented for the purpose of correcting the aberration characteristic are calculated with a travel-generating optimization algorithm, which is also referred to as “manipulator change model”. For example, such optimization algorithms are described in WO 2010/034674 A1.

To enable the most accurate correction possible for the aberrations of the projection lens that form over the course of the exposure operation, the aforementioned regular measurement of the aberration characteristic is generally implemented at a plurality of field points of the projection lens. However, the measurement duration increases with the number of field points measured. Since the exposure process of semiconductor wafers needs to be interrupted to perform the aberration measurement, the productivity of the projection exposure apparatus is reduced with the number of measured field points. Hence, it is customary to measure only a limited number of field points.

### SUMMARY

One object of the invention is providing methods and a projection exposure apparatus of the type set forth above, whereby the aforementioned problems may be solved and, in particular, the aberrations that form over the course of the exposure operation of the projection exposure apparatus may be corrected with improved accuracy and, at the same time, the productivity of the projection exposure apparatus may be maintained at a high level.

According to one formulation of the invention, the aforementioned problem may for example be addressed by a method for evaluating measured values of at least one aberration of a projection lens of a microlithographic projection exposure apparatus that have been determined at a plurality of field points in a field plane of the projection lens, wherein the projection lens comprises a plurality of optical elements for guiding an exposure radiation and a manipulator system, with which at least one of the optical elements is configured to be manipulated in at least one degree of freedom of movement in order to carry out a rigid body movement. The method comprises the following steps: providing a fit function which comprises a polynomial function that depends on two variables in the form of the spatial coordinates which define the field plane and a further term, wherein the further term comprises rigid body sensitivities for multiple locations in the field plane that each describe a dependence of the at least one aberration on a degree of freedom of movement at the relevant locations, the degree of freedom being controllable by the manipulator system, and extrapolating the measured values determined at the plurality of field points to further field points of the projection lens by fitting the fit function to the determined measured values.

A field point of a projection lens should be understood to mean a point in a field plane of the projection lens. In particular, a possible field plane is a substrate plane of the projection lens, i.e. a plane into which mask structures of a lithography mask are imaged and in which a substrate, in particular a semiconductor substrate, is therefore arranged. The polynomial dependent on two variables may also be referred to as a bivariate polynomial.

According to an embodiment, the manipulator system is configured to manipulate a plurality of the optical elements, in particular all optical elements, in each case in at least one degree of freedom of movement, in particular in multiple and preferably in all degrees of freedom of movement, in order to carry out a rigid body movement.

Hence, for at least one location in the field plane, the respective sensitivity describes the dependence of the at least one aberration on degrees of freedom of movement of the manipulator system. For example, the degrees of freedom of movement may comprise all rigid body degrees of freedom of the optical element, i.e. respective translations and rotations of the optical elements with respect to all three spatial dimensions in each case.

The interruption of the exposure operation, which is required for the aberration measurement, can be kept short as a result of the provision of a fit function with the polynomial function and the described further term and the extrapolation of the measured values determined at the plurality of field points to further field points of the projection lens by fitting the fit function.

In addition to the aberrations of the measured field points, the fit function at the same time allows the use of aberrations of further field points, which were determined with great accuracy, for the manipulator correction. By taking account of the further term with the at least one sensitivity in the fit function, it is possible to better take into account aberrations, which are generated by system drifts occurring simultaneously with the heating of the optical elements, during the fit to the determined measured values. The generation of the aberrations of further field points with high accuracy also improves the accuracy of the manipulator correction.

According to an embodiment, the further term comprises multiple rigid body sensitivities for the at least one location in the field plane. These describe a dependence of the at least one aberration on multiple degrees of freedom of movement at the relevant location, the degrees of freedom being controllable by the manipulator system.

According to a further embodiment, the further term in each case comprises one or more rigid body sensitivities for multiple locations in the field plane.

According to a further embodiment, the degrees of freedom of movement of the manipulator system in each case comprise at least one degree of freedom of translation and at least one degree of freedom of rotation of multiple optical elements of the optical elements.

According to a further embodiment, the at least one aberration comprises one or more Zernike coefficients of a wavefront aberration of the projection lens.

According to a further embodiment, the polynomial function of the fit function is configured to model a component of the field-point-dependent distribution of the aberration that is generated by the shape deviations of the optical elements. In particular, the shape deviation may be caused by inhomogeneous temperature distributions in the optical elements.

According to a further embodiment, the polynomial function of the fit function is a two-dimensional polynomial of at least third order. That is to say, the polynomial function contains at least one term in which the sum of the powers of the two function variables, e.g. x and y, is three, e.g. x3, x2y or y3.

According to a further embodiment, respective extrapolated values are determined both for the field points at which the measured values were determined and for the further field points by fitting the fit function to the measured values during the extrapolation of the measured values.

Furthermore, according to a further formulation of the invention, a method is provided for operating a microlithographic projection exposure apparatus having a projection lens that comprises a plurality of optical elements and a manipulator system. The method comprises the following steps: determining measured values for at least one aberration of the projection lens at a plurality of field points in a field plane of the projection lens, evaluating the determined measured values using the method according to any of the above-described embodiments for determining extrapolated values of the at least one aberration at further field points and determining a travel command for the manipulator system in order to correct the at least one aberration using the extrapolated values.

According to an embodiment of the method for operating a projection exposure apparatus, the travel command is determined with an optimization process.

According to an embodiment of the method for evaluating measured values or of the method for operating a projection exposure apparatus, the projection exposure apparatus is designed for operating in the extreme ultraviolet (EUV) wavelength range.

Furthermore, according to a further formulation, the invention provides for a microlithographic projection exposure apparatus. The latter comprises a projection lens for imaging mask structures onto a substrate having a plurality of optical elements, a manipulator system that is configured to manipulate at least one of the optical elements in at least one degree of freedom of movement in order to carry out a rigid body movement, a measuring module for determining measured values of at least one aberration of the projection lens at a plurality of field points in a field plane of the projection lens, and an extrapolation device for extrapolating the measured values determined at the plurality of field points to further field points of the projection lens having a fitting module that is configured to fit a fit function to the determined measured values. The fit function comprises a polynomial function that depends on two variables in the form of the spatial coordinates which define the field plane and a further term. The further term comprises rigid body sensitivities for multiple locations in the field plane that each describe a dependence of the at least one aberration on a degree of freedom of movement at the relevant locations, the degree of freedom being controllable by the manipulator system.

According to an embodiment of the projection exposure apparatus, the extrapolation device furthermore comprises an aberration value determination module that is configured to determine aberration values for the further field points on the basis of the fitted fit function.

According to a further embodiment, the projection exposure apparatus is designed for operating in the EUV wavelength range.

The features specified with respect to the aforementioned embodiments, exemplary embodiments or embodiment variants, etc., of the method for evaluating measured values or of the method for operating a projection exposure apparatus can be correspondingly applied to the projection exposure apparatus, and vice versa. These and other features of the embodiments will be explained in the description of the figures and in the claims. The individual features may be implemented, either separately or in combination, as embodiments. Furthermore, they may describe advantageous embodiments that are independently protectable and protection for which is claimed only during or after pendency of the application, as the case may be.

### BRIEF DESCRIPTION OF THE DRAWINGS

The aforementioned features and further advantageous features will be illustrated in the following detailed description of exemplary embodiments or of embodiments with reference to the attached schematic drawings, in which:

FIG. 1 shows an illustration of an exemplary embodiment of a microlithographic projection exposure apparatus having a measuring module for determining measured values of a wavefront aberration at a plurality of field points and an extrapolation device for extrapolating the measured values to further field points, and

FIG. 2 shows a detailed illustration of the extrapolation device according to FIG. 1.

### DETAILED DESCRIPTION

In the exemplary embodiments or embodiments or embodiment variants described below, elements that are functionally or structurally similar or analogous to one another are provided with the same or similar reference signs as far as possible. Therefore, for understanding the features of the individual elements of a specific exemplary embodiment, reference should be made to the description of other exemplary embodiments or the general description.

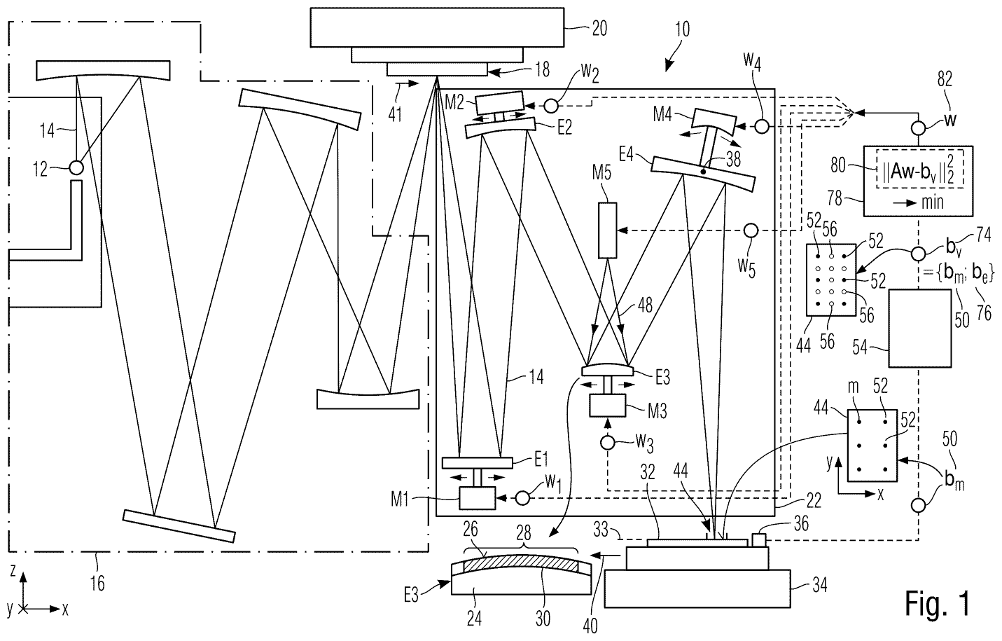

In order to facilitate the description, a Cartesian xyz-coordinate system is indicated in a drawing, from which system the respective positional relationship of the components illustrated in the figure is evident. In FIG. 1, the y-direction runs perpendicularly to the plane of the drawing into said plane, the x-direction runs toward the right and the z-direction runs upward.

FIG. 1 shows an exemplary embodiment of a microlithographic projection exposure apparatus 10. The projection exposure apparatus 10 is embodied for operating in the EUV wavelength range, i.e. with electromagnetic radiation at a wavelength of shorter than 100 nm, in particular a wavelength at approximately 13.5 nm or approximately 6.8 nm. All optical elements of the projection exposure apparatus 10 are therefore embodied as mirrors. However, embodiments of the invention are not limited to projection exposure apparatuses in the EUV wavelength range. Further exemplary embodiments are for example designed for operating wavelengths in the UV range, such as 365 nm, 248 nm or 193 nm. In that case, at least some of the optical elements are configured as conventional transmission lens elements.

The projection exposure apparatus 10 comprises an exposure radiation source 12 for generating exposure radiation 14. In the present case, the exposure radiation source 12 is embodied as an EUV source and may for example comprise a plasma radiation source. The exposure radiation 14 first passes through an illumination system 16 and is directed by the latter onto a mask 18. The illumination system 16 is configured to generate different angular distributions of the exposure radiation 14 incident on the mask 18. The illumination system 16 configures the angular distribution of the exposure radiation 14 incident on the mask 18 on the basis of an illumination setting desired by the user. Examples of illumination settings that can be chosen include what is known as a dipole illumination, an annular illumination and a quadrupole illumination.

The mask 18 comprises mask structures to be imaged onto a substrate 32, which is in the form of a semiconductor wafer and arranged in a field plane 33, and is displaceably mounted on a mask displacement stage 20. As illustrated in FIG. 1, the mask 18 may be embodied as a reflection mask, or it may also be configured as a transmission mask in an alternative, especially for UV lithography. In this exemplary embodiment, the exposure radiation 14 is reflected off the mask 18 and thereupon passes through a projection lens 22 that is configured to image the mask structures onto the substrate 32. The exposure radiation 14 is guided within the projection lens 22 via a multiplicity of optical elements.

The projection lens 22 comprises four optical elements E1 to E4 in the form of mirrors. All optical elements are mounted in a movable manner. To this end, a respective mechanical manipulator M1 to M4 is assigned to each of the optical elements E1 to E4. The manipulators M1, M2 and M3 each enable a displacement of the assigned optical elements E1, E2 and E3 substantially in the x-direction and therefore substantially parallel to the plane in which the respective reflecting surface of the optical elements lies.

The manipulator M4 is configured to tilt the optical element E4 by rotation about a tilt axis 38 arranged parallel to the y-axis. As a result, the angle of the reflecting surface of E4 is modified in relation to the incident radiation. Further degrees of freedom for the manipulators are conceivable. Thus, for example, provision can be made for a displacement of a relevant optical element across the optical surface thereof or for a rotation about a reference axis perpendicular to the reflecting surface. According to an embodiment, each of the optical elements E1 to E4 is manipulable in all six rigid body degrees of freedom, i.e. in the three degrees of freedom of translation (x-, y- and z-directions) and in the three degrees of freedom of rotation (rotations with respect to the x-, y- and z-axes).

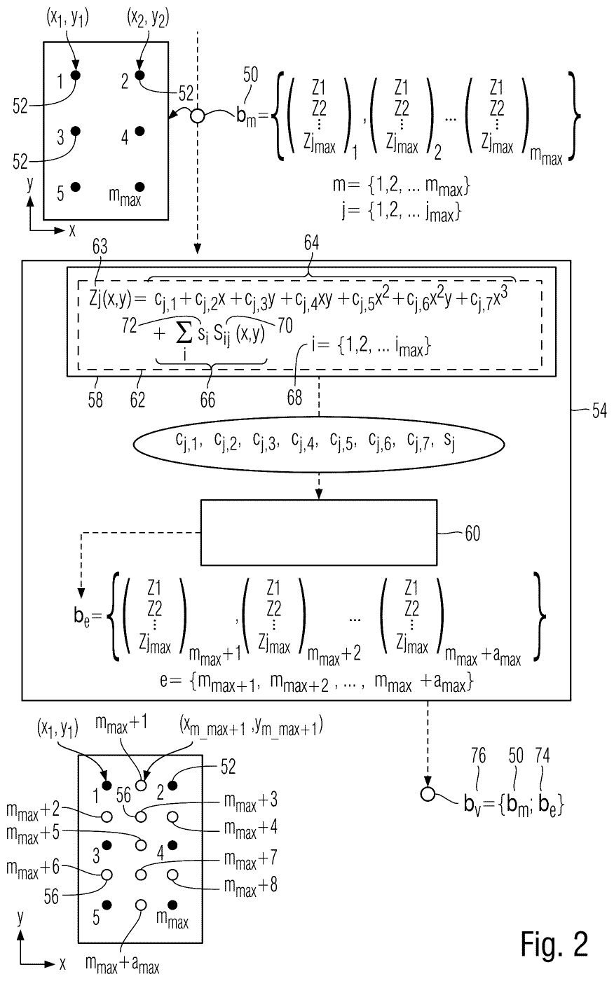

In other words, the manipulator system formed by the manipulators M1 to M4 enables the movement of the optical elements E1 to E4 in one or more degrees of freedom of movement in each case, wherein the latter may also be referred to as rigid body degrees of freedom. All degrees of freedom of movement that can be set at the various optical elements E1 to E4 with the manipulator system formed by the manipulators M1 to M4 are denoted by the index i (reference sign 68) in FIG. 2. In this case, i={1, 2, . . . iₘₐₓ}, where imax is the sum of all degrees of freedom of movement of the manipulators M1 to M4; hence, the largest possible value for imax is 24, i.e. four times six rigid body degrees of freedom per manipulator M1 to M4.

In general terms, each one of the manipulators M1 to M4 illustrated here is provided to bring about a displacement of the assigned optical element E1 to E4 by performing a rigid body movement along a predetermined travel w1 to w4. For example, each one of these travels w1 to w4 can combine translations in different directions, tilts and/or rotations in any desired manner. In other words, the travels w1 to w4 comprise the control instructions for all degrees of freedom of movement i of the manipulators M1 to M4.

In addition, it is also possible to provide manipulators that are configured to implement a change of a different kind in a state variable of the assigned optical element through an appropriate actuation of the manipulator, for example by applying a specific temperature distribution or a specific force distribution to the optical element. In this case, the travel w may be characterized by a change in the temperature distribution on the optical element or the application of local stress to an optical element in the form of a deformable lens element or in the form of a deformable mirror.

As an example of a manipulator for applying a specific temperature distribution to an optical element, the optical element E3 is assigned a heating device in FIG. 1, this heating device being referred to as manipulator M5. The optical element E3 is embodied as a mirror having a mirror substrate 24 and a reflecting surface 26. FIG. 1 additionally illustrates the optical element E3 in a schematic detailed view. The surface 26 comprises a surface portion 28, under which a compacted volume portion 30 is arranged. For example, a predetermined surface shape of the surface portion 28 is realized very accurately with the compaction of the volume portion 30.

On the basis of a control signal in the form of a travel w5, the heating device M5 serves for spatially dependent heating of the surface portion 28 so as to influence the relaxation of the compacted volume portion 30. To this end, the heating device M5 comprises irradiation equipment having an infrared laser and a deflection device for guiding the laser beam over the entire surface of the surface portion 28. In this case, infrared light 48 sweeps over the surface portion 28 line by line or in the shape of a spiral. Depending on the specified local intensity, an appropriate dwell time of the laser beam is provided for at each position on the surface portion 28. Alternatively, any other type of electromagnetic radiation may also be used for heating the surface portion 28.

The substrate 32 is displaceably mounted on a substrate displacement stage 34. In the exemplary embodiment illustrated, the projection exposure apparatus 10 is in the form of what is known as a scanner. In the latter, the exposure of a substrate 32 involves the displacement of this substrate in a displacement direction 40, the negative x-direction in the illustrated case, with the substrate displacement stage 34 and the displacement of the mask 18 in the opposite displacement direction 41, the positive x-direction in the illustrated case, with the mask displacement stage 20. In that case, a scanner slot 44 is moved over the substrate 32 during the exposure of the said substrate 32, and a field on the substrate 32 is exposed in a scanning process. In an alternative, the projection exposure apparatus 10 may be in the form of what is known as a stepper.

Furthermore, a measuring module 36 for determining measured values 50 of at least one aberration of the projection lens 22 at different field points 52 is arranged next to the substrate 32 on the substrate displacement stage 34. In the present exemplary embodiment, the measuring module 36 is configured as wavefront measuring equipment for measuring wavefront deviations or wavefront aberrations of the projection lens 22 that are represented through the Zernike coefficients. For example, these measurements are performed with the aid of phase-shifting interferometry techniques, for instance shearing interferometry or point diffraction interferometry. In an alternative, the measuring module 36 may also serve to measure aberrations in the form of lithographic errors, for example overlay errors and/or focus errors.

In the present exemplary embodiment, the measuring module 36 determines a vector b of Zernike coefficients as measured values 50 at each measured field point 52. For example, FIG. 1 illustrates six measured field points 52 in the region of the scanner slot 44. These are denoted by the counter m, where m runs from 1 to mmax=6 (m={1, 2, . . . mₘₐₓ})—cf. FIG. 2, top left. Hence, the set of vectors bₘ denotes mₘₐₓ vectors b, which comprise a predetermined selection of Zernike coefficients Zⱼ, for instance all Zernike coefficients Z1, Z2, . . . , Zjₘₐₓ up to the Zernike coefficient with the index jₘₐₓ (j={1, 2, . . . jₘₐₓ}).

$${b}_{m} = \{ {( \begin{matrix}Z 1 \\ Z 2 \\ ⋮ \\ {Zj}_{max}\end{matrix} )}_{1} , {( \begin{matrix}Z 1 \\ Z 2 \\ ⋮ \\ {Zj}_{max}\end{matrix} )}_{2} … {( \begin{matrix}Z 1 \\ Z 2 \\ ⋮ \\ {Zj}_{max}\end{matrix} )}_{{m}_{max}} \} \qquad ( 1 )$$

In the present application, the Zernike functions

$${Z}_{m}^{n} ,$$

as known from e.g. Chapter 13.2.3 in the textbook “Optical Shop Testing”, 2^{nd} Edition (1992) by Daniel Malacara, pub. John Wiley & Sons, Inc., are denoted by Zⱼ in accordance with the so-called fringe sorting, as described in e.g. paragraphs [0125]-[0129] in US 2013/0188246A1, with bⱼ then being the Zernike coefficients assigned to the respective Zernike polynomials (also referred to as “Zernike functions”). The fringe ordering is for example illustrated in Table 20-2 on page 215 of the “Handbook of Optical Systems”, Vol. 2 by H. Gross, 2005 Wiley-VCH Verlag GmbH & Co. KGaA, Weinheim. A wavefront deviation W(ρ,Φ) at a point in the object plane of the projection lens is then series-expanded as follows on the basis of the polar coordinates (ρ, Φ) of the pupil plane:

$$W ( ρ , Φ ) = {\sum }_{j} {b}_{j} \cdot {Z}_{j} ( ρ , Φ ) \qquad ( 2 )$$

While the Zernike polynomials are denoted by Zj, i.e., with the subscript index j, the Zernike coefficients are denoted by bj in term (2). It should be noted here that the Zernike coefficients bj are often also denoted by Zj, i.e. with a normally written index, in the art, for example Z5 and Z6 representing astigmatism. This designation is also used in this text, for instance in expression (1).

The measured values 50 in the form of the vectors bm measured at the field points 52 are transmitted to an extrapolation device 54, which serves to extrapolate the measured values 50 to further field points 56 of the projection lens 22. In FIG. 1, the further field points 56 are plotted as small circles in the region of the substrate-side field plane 33 illuminated by the scanner slot 44, while the measured field points 52 are depicted as filled-in points. The same representation is found in FIG. 2, bottom left, where aₘₐₓ=9 further field points 56 are illustrated. For these, the aforementioned numbering of the measured field points 52 is continued (1 to mₘₐₓ=6), and so the further field points 56 are assigned the numbers 7 to 15 (mₘₐₓ+1, mₘₐₓ+2, . . . ).

The extrapolation device 54 provides a larger set of values 74 of aberrations in the form of a set of vectors bv, which comprise respective vectors b with the corresponding, aforementioned Zernike coefficients for both the measured field points 52 and the further afield points 56.

According to an embodiment, the set of vectors bᵥ comprises the measured values 50, i.e. the set of vectors bₘ, for the measured field points 52 and extrapolated aberration values 76 in the form of a set of vectors be for the further field points 56. In this case, be comprises a total of e={mₘₐₓ+1, mₘₐₓ+2, . . . , mₘₐₓ+aₘₐₓ} vectors b:

$${b}_{e} = \{ {( \begin{matrix}Z 1 \\ Z 2 \\ ⋮ \\ {Zj}_{max}\end{matrix} )}_{{m}_{max} + 1} , {( \begin{matrix}Z 1 \\ Z 2 \\ ⋮ \\ {Zj}_{max}\end{matrix} )}_{{m}_{max} + 2} … {( \begin{matrix}Z 1 \\ Z 2 \\ ⋮ \\ {Zj}_{max}\end{matrix} )}_{{m}_{max} + {a}_{max}} \} \qquad ( 3 )$$

According to a further embodiment, not depicted here, the set of vectors bv also comprises the extrapolated aberration values for the measured field points 52, i.e. bv=be applies in this case, and the set of vectors be comprises a total of e={1, 2, . . . , mₘₐₓ+aₘₐₓ} vectors b.

As illustrated in FIG. 2, the extrapolation device 54 comprises a fitting module 58 and an aberration value determination module 60. The fitting module 58 is configured to fit a fit function 62 to the determined measured values 50 (set of vectors bₘ). According to an exemplary embodiment, the fit function 62 reads as follows:

$$Zj ( x , y ) = {c}_{j , 1} + {c}_{j , 2} x + {c}_{j , 3} y + {c}_{j , 4} xy + {c}_{j , 5} {x}^{2} + {c}_{j , 6} {x}^{2} y + {c}_{j , 7} {x}^{3} + {\sum }_{i} {s}_{i} {S}_{ij} ( x , y ) \qquad ( 4 )$$

Here, Zj(x,y) denotes a field-point-dependent distribution 63 of the aberration in the form of all Zernike coefficients listed in bₘ as a function of the spatial coordinates x and y in the field plane 33. With

$${c}_{j , 1} + {c}_{j , 2} x + {c}_{j , 3} y + {c}_{j , 4} xy + {c}_{j , 5} {x}^{2} + {c}_{j , 6} {x}^{2} y + {c}_{j , 7} {x}^{3} , \qquad ( 5 )$$

the fit function 62 according to (4) comprises a polynomial function 64 and with

$${\sum }_{i} {s}_{i} {S}_{ij} ( x , y ) , \qquad ( 6 )$$

it comprises a further term 66. The polynomial function 64 is a two-dimensional function depending on the spatial coordinates x and y defining the field plane 33. In the present embodiment, the polynomial function 64 is a two-dimensional polynomial of third order, i.e. the polynomial function 64 contains at least one term, the terms c_{j,6} x²y and c_{j,7} x³ in the present case, in which the sum of the powers of the two function variables x and y is three. The polynomial function 64 is configured to model a component of the field-point-dependent aberration distribution Zj(x,y), which is generated by shape deviations of the optical elements E1 to E4.

For each Zernike coefficient Zⱼ and each degree of freedom of movement i of the manipulator system formed by the manipulators M1 to M4, the further term 66 comprises a rigid body sensitivity Sij(x,y) (reference sign 70) and a sensitivity coefficient si (reference sign 72), wherein the sum is formed by the products of si and Sij(x,y).

The rigid body sensitivities Sᵢⱼ(x,y) each describe a dependence of an aberration in the form of the relevant Zernike coefficient Zj on the relevant degree of freedom of movement i. As explained above, i denotes the degrees of freedom of movement that are controllable by the manipulator system formed by the manipulators M1 to M4. The rigid body sensitivities Sij(x,y) are each a two-dimensional function depending on the spatial coordinates x and y of the field plane 33. This two-dimensional function may also be discretized, i.e. the rigid body sensitivities Sij(x,y) may each be represented by a set of discrete values specified for certain field points, i.e.

$${S}_{ij} ( x , y ) = \{ {S}_{ij}^{x 1 , y 1} , {S}_{ij}^{x 1 , y 2} , {S}_{ij}^{x 2 , y 1} , {S}_{ij}^{x 2 , y 2} , … \} .$$

Since the rigid body sensitivities Sij(x,y) are indexed with i and j, the term 66 in each case comprises a multiplicity of rigid body sensitivities for each location in the field plane 33.

In the fitting module 58, the fit function 62 is fitted to the measured values 50 with a fitting algorithm adapted to this end. As a result of the fitting, a set of coefficients c_{j,1}, c_{j,2}, c_{j,3}, c_{j,4}, c_{j,5}, c_{j,6} and c_{j,7} or a matrix C with j columns and 7 rows, in which the matrix elements are the coefficients, is determined for each Zernike coefficient Zj. Furthermore, the fitting algorithm determines a set of sensitivity coefficients si for the relevant degrees of freedom of movement i of the manipulator system formed by the manipulators M1 to M4.

Finally, on the basis of the coefficients c_{j,1}, c_{j,2}, c_{j,3}, c_{j,4}, c_{j,5}, c_{j,6}, c_{j,7} and si determined by the fitting module 58, the aberration value determination module 60 determines the relevant Zernike coefficients at the further field points 56, i.e. the vectors b at the further field points (x_{m_max+1}, y_{m_max+1}), (x_{m_max+2}, y_{m_max+2}), . . . (x_{m_max+a_max}, y_{m_max+a_max}), and hence the set of vectors be according to the aforementioned first embodiment. Hence, the extrapolation device 54 provides the set of vectors bᵥ from the vectors bₘ of the measured field points 52 and the vectors be of the further field points 56 determined by extrapolation.

According to a further embodiment, the vectors b for the field points 52 may additionally also be redetermined by extrapolation in the aberration value determination module 60 as already mentioned above, and so the set of vectors be comprises extrapolated vectors b for both the field points 52 and for the field points 56. In this case, the set of vectors bv with the enlarged set of values 74 of aberrations corresponds to the set of vectors be.

As illustrated in FIG. 1, the set of vectors bv with the aberration values for the extended number of field points 52 and 56 is transmitted to a correction signal determination unit 78. The latter is configured to determine a travel command w (reference sign 82) with travels w1 to w5 for the manipulators M1 to M5 on the basis of the set of vectors bv. That is to say, the correction signal determination unit 78 determines travels w1 to w4 that specify rigid body movements of the mechanical manipulators M1 to M4 and a travel w5 that specifies an intensity distribution of the heating energy for the heating device M5. In FIG. 1, the travel command 82 is represented by vector w.

To determine the travels w1 to w5, the correction signal determination unit 78 may use an optimization algorithm, for example. According to an embodiment, the optimization algorithm serves to optimize a merit function 80 taking into account at least one constraint. According to an embodiment variant, the optimization algorithm is configured to solve the following optimization problem:

$$min {‖ Aw - {b}_{v} ‖}_{2}^{2} \qquad ( 7 )$$

In this case,

$${‖ Aw - {b}_{v} ‖}_{2}^{2}$$

is the merit function 80 and A is a sensitivity matrix that describes the relationship between an adjustment of the manipulators M1 to M5 by a standard travel wᵢ⁰ and a change in bᵥ resulting therefrom.

The above description of exemplary embodiments, embodiments or embodiment variants should be understood to be by way of example. The disclosure effected thereby firstly enables a person skilled in the art to understand the present invention and the advantages associated therewith, and secondly encompasses alterations and modifications of the described structures and methods that will be apparent to persons skilled in the art. Accordingly, the applicant seeks to cover any and all such alterations and modifications, insofar as they fall within the spirit and scope of the invention as defined by the accompanying claims, and equivalents thereof.

### LIST OF REFERENCE SIGNS

10 Projection exposure apparatus
12 Exposure radiation source
14 Exposure radiation
16 Illumination system
18 Mask
20 Mask displacement stage
22 Projection lens
24 Mirror substrate
26 Surface
28 Surface portion
30 Compacted volume portion
32 Substrate
33 Field plane
34 Substrate displacement stage
36 Measuring module
38 Tilt axis
40 Displacement direction of the substrate displacement stage
41 Displacement direction of the mask displacement stage
42 Illumination setting
44 Scanner slot
48 Infrared light
50 Measured values bₘ
52 Measured field points
54 Extrapolation device
56 Further field points
58 Fitting module
60 Aberration value determination module
62 Fit function
63 Field-point-dependent distribution of the aberration
64 Polynomial function
66 Further term
68 Degrees of freedom of movement of the manipulators M1 to M4
70 Rigid body sensitivity
72 Sensitivity coefficient
74 Larger set of values of aberrations by
76 Extrapolated aberration values be
78 Correction signal determination unit
80 Merit function
82 Travel command
E1-E4 Optical elements
M1-M4 Mechanical manipulators
M5 Heating device
w₁-w₅ Travels

What is claimed is:

1. A method for evaluating measured values of at least one aberration of a projection lens of a microlithographic projection exposure apparatus that have been determined at a plurality of field points in a field plane of the projection lens, wherein the projection lens comprises a plurality of optical elements arranged to guide exposure radiation and a manipulator system configured to manipulate at least one of the optical elements in at least one degree of freedom of movement for carrying out a rigid body movement, wherein the method comprises:
providing a fit function which comprises a polynomial function that depends on two variables formed as spatial coordinates which define the field plane and a further term, wherein the further term comprises rigid body sensitivities for multiple locations in the field plane that each describe a dependence of the at least one aberration on a degree of freedom of movement at the locations, and wherein the manipulator system is configured to control the degree of freedom of movement, and
extrapolating the measured values determined at the plurality of field points to further field points of the projection lens by fitting the fit function to the determined measured values.

2. The method as claimed in claim 1,
wherein the further term comprises multiple rigid body sensitivities for the multiple locations in the field plane.

3. The method as claimed in claim 1,
wherein the further term in each case comprises at least one rigid body sensitivity for multiple locations in the field plane.

4. The method as claimed in claim 1,
wherein the manipulator system controls multiple degrees of freedom of movement, in each case comprising at least one degree of freedom of translation and at least one degree of freedom of rotation of multiple ones of the optical elements.

5. The method as claimed in claim 1,
wherein the at least one aberration comprises one or more Zernike coefficients of a wavefront aberration of the projection lens.

6. The method as claimed in claim 1,
wherein the polynomial function of the fit function is configured to model a component of a field-point-dependent distribution of the aberration that is generated by shape deviations of the optical elements.

7. The method as claimed in claim 1,
wherein the polynomial function of the fit function is a two-dimensional polynomial of at least third order.

8. The method as claimed in claim 1,
wherein respective extrapolated values are determined both for the field points at which the measured values were determined and for the further field points by fitting the fit function to the measured values during said extrapolating of the measured values.

9. A method for operating a microlithographic projection exposure apparatus having a projection lens that comprises a plurality of optical elements and a manipulator system, wherein the method comprises:
determining measured values for at least one aberration of the projection lens at a plurality of field points in a field plane of the projection lens,
evaluating the determined measured values with the method as claimed in claim 1 for determining extrapolated values of the at least one aberration at further field points,
determining a travel command for the manipulator system for correcting the at least one aberration using the extrapolated values.

10. The method as claimed in claim 9,
wherein the travel command is determined with an optimization process.

11. The method as claimed in claim 1,
wherein the projection exposure apparatus is configured to operate in the extreme ultraviolet wavelength range.

12. The method as claimed in claim 9,
wherein the projection exposure apparatus is configured to operate in the extreme ultraviolet wavelength range.

13. A microlithographic projection exposure apparatus comprising:
a projection lens configured to image mask structures onto a substrate and having a plurality of optical elements,
a manipulator system configured to manipulate at least one of the optical elements in at least one degree of freedom of movement for carrying out a rigid body movement,
a measuring module configured to determine measured values of at least one aberration of the projection lens at a plurality of field points in a field plane of the projection lens, and
an extrapolation device configured to extrapolate the measured values determined at the plurality of field points to further field points of the projection lens and having a fitting module that is configured to fit a fit function to the determined measured values, wherein the fit function comprises a polynomial function that depends on two variables formed as spatial coordinates which define the field plane and a further term that comprises rigid body sensitivities for multiple locations in the field plane that each describe a dependence of the at least one aberration on a degree of freedom of movement at the locations, and wherein the manipulator system is configured to control the degree of freedom of movement.

14. The projection exposure apparatus as claimed in claim 13,
wherein the extrapolation device further comprises an aberration value determination module configured to determine aberration values for the further field points based on the fitted fit function.

15. The projection exposure apparatus as claimed in claim 14,
configured to operate in the extreme ultraviolet wavelength range.
